(19) United States
(12) Patent Application Publication
(10) Pub. No.: US 2015/0179835 A1
(43) Pub. Date: Jun. 25, 2015

(54) Solar Cell

(71) Applicant: AU Optronics Corporation, Hsin-Chu (TW)

(72) Inventors: Yi-Jiunn CHIEN, HSIN-CHU (TW); Jay CHANG, HSIN-CHU (TW)

(73) Assignee: AU Optronics Corporation, Hsin-Chu (TW)

(21) Appl. No.: 14/266,004

(22) Filed: Apr. 30, 2014

(30) Foreign Application Priority Data
Dec. 23, 2013 (CN) 201310714732.2

(51) Int. Cl. H01L 31/0224; H01L 31/02

(52) U.S. Cl. CPC H01L 31/022425; H01L 31/022475; H01L 31/0201

(57) ABSTRACT

A solar cell includes an opto-electrical conversion structure, a first electrically-conductive structure, and a second electrically-conductive structure. The opto-electrical conversion structure has a light receiving surface and a back surface opposite to the light receiving surface. The first electrically-conductive structure is disposed on the light receiving surface and electrically connected to the opto-electrical conversion structure. The first electrically-conductive structure includes a first transparent electrically-conductive layer, an electrode structure, and a second transparent electrically-conductive layer. The first transparent electrically-conductive layer is disposed on the light receiving surface of the opto-electrical conversion structure. At least one portion of the first transparent electrically-conductive layer is disposed between the electrode structure and the light receiving surface of the opto-electrical conversion structure. The second transparent electrically-conductive layer covers the electrode structure and the first transparent electrically-conductive layer. The second electrically-conductive structure is disposed on the back surface of the opto-electrical conversion structure.

### RELATED APPLICATIONS

This application claims priority to Chinese Application Serial Number 201310714732.2, filed Dec. 23, 2013, which is herein incorporated by reference.

### BACKGROUND

1. Field of Disclosure

The present disclosure relates to a solar cell.

2. Description of Background

To shrink the size of a metal electrode having single metal layer of a solar cell is one of the main trends in a solar cell manufacturing process. Small metal electrode can reduce the area of the metal electrode having single metal layer covering a photo-electric conversion structure, thereby enhancing the light capture efficiency of the solar cell. However, the size reduction of metal electrode having single metal layer results in the resistance increase of the solar cell, and the increased resistance may adversely reduce the efficiency of the solar cell.

Moreover, although a copper plating process may be used to manufacture small-sized metal electrode having single metal layer, most of the cross-sections of the metal electrode having single metal layer is mushroom-shaped due to the properties of the electroplating process. The mushroom-shaped cross-section increases the area of the metal electrode having single metal layer covering the photo-electric conversion structure and reduces the area of the metal electrode having single metal layer contacting a transparent electrically-conductive layer. The mushroom-shaped cross-section decreases the light capture efficiency, and the reduced light-blocking area of the metal electrode having single metal layer increases the resistance between the metal electrode having single metal layer and the transparent electrically-conductive layer, in which both factors affect the conversion efficiency of the solar cell.

### SUMMARY

An aspect of the present disclosure is to provide a solar cell including a photo-electric conversion structure, a first electrically-conductive structure, and a second electrically-conductive structure. The photo-electric conversion structure has a light receiving surface and a back surface opposite to the light receiving surface. The first electrically-conductive structure is disposed on the light receiving surface of the photo-electric conversion structure and electrically connected to the photo-electric conversion structure. The first electrically-conductive structure includes a first transparent electrically-conductive layer, an electrode structure, and a second transparent electrically-conductive layer. The first transparent electrically-conductive layer is disposed on the light receiving surface of the photo-electric conversion structure. At least one portion of the first transparent electrically-conductive layer is disposed between the electrode structure and the light receiving surface of the photo-electric conversion structure. The second transparent electrically-conductive layer covers the electrode structure and the first transparent electrically-conductive layer. The second electrically-conductive structure is disposed on the back surface of the photo-electric conversion structure.

In one or more embodiments, the first electrically-conductive structure further includes a buffer layer disposed between the electrode structure and the second transparent electrically-conductive layer, wherein the buffer layer is cover on a top surface and side wall of the electrode structure.

In one or more embodiments, the buffer layer is formed from at least one of zinc, titanium, tin, and indium.

In one or more embodiments, the first electrically-conductive structure further includes a seed layer disposed between the electrode structure and the first transparent electrically-conductive layer.

In one or more embodiments, the seed layer comprises copper.

In one or more embodiments, a thickness of the first transparent electrically-conductive layer substantially ranges from about 10 nm to about 100 nm.

In one or more embodiments, the electrode structure includes bus electrodes and finger electrodes. The finger electrodes are interlacing arranged with the bus electrodes, and electrically connected to the bus electrodes.

In one or more embodiments, a width of the finger electrode is increasing in a direction away from the first transparent electrically-conductive layer.

In one or more embodiments, a width of the finger electrode is decreasing in a direction away from the first transparent electrically-conductive layer.

In one or more embodiments, the electrode structure comprises copper or silver.

### BRIEF DESCRIPTION OF THE DRAWINGS

FIG. 1 is a three dimensional view of a solar cell according to one embodiment of the present disclosure;

FIG. 2 is a cross-sectional view viewed along line A-A of FIG. 1 according to one embodiment;

FIG. 3 is a top view of the solar cell in FIG. 1; and

FIG. 4 is a cross-sectional view viewed along line A-A of FIG. 1 according to another embodiment.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

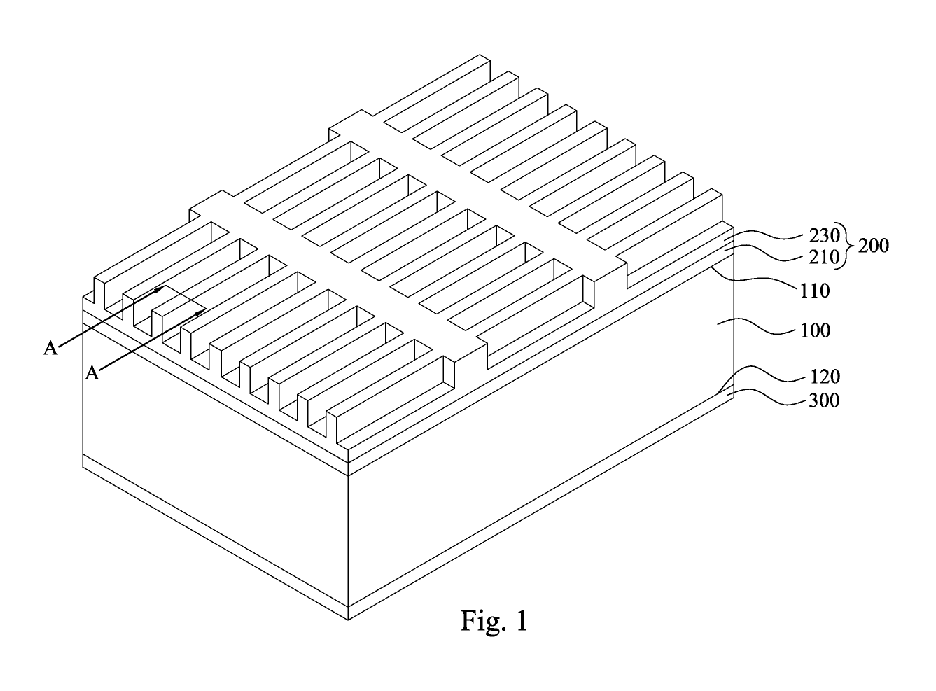

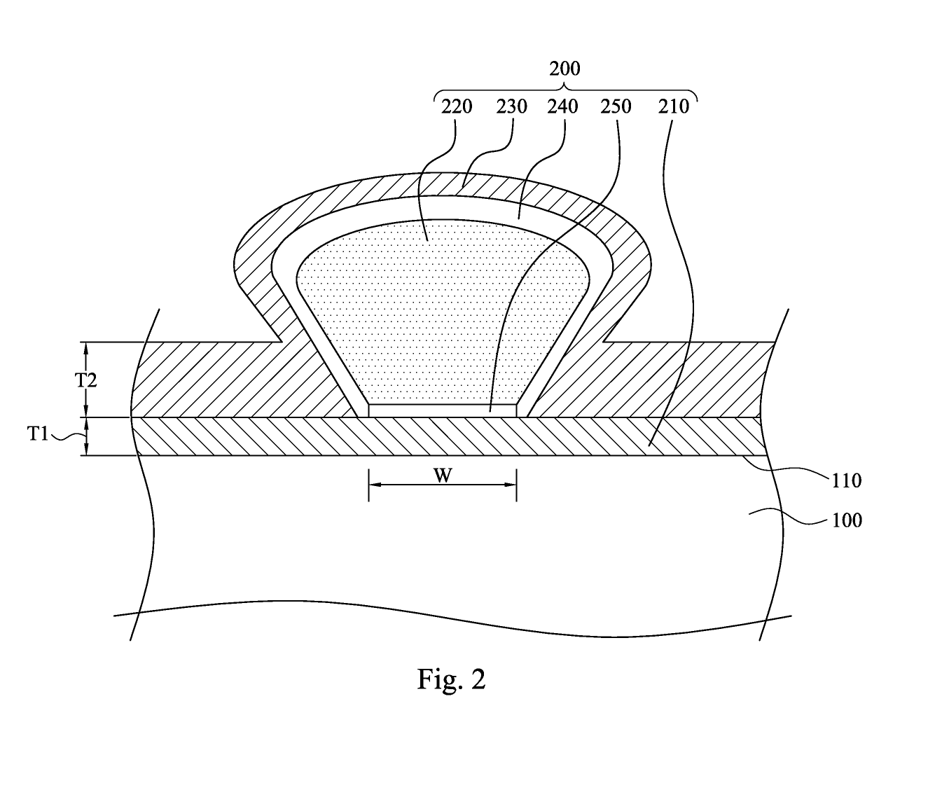

FIG. 1 is a three dimensional view of a solar cell according to one embodiment of the present disclosure, and FIG. 2 is a cross sectional view viewed along line A-A of FIG. 1 according to one embodiment. Reference is made to FIGS. 1 and 2. The solar cell includes an opto-electrical conversion structure (or namely photo-electric conversion structure) 100, a first electrically-conductive structure 200, and a second electrically-conductive structure 300. The opto-electrical conversion structure 100 has a light receiving surface 110 and a back surface 120 opposite to the light receiving surface 110. The first electrically-conductive structure 200 is disposed on the light receiving surface 110 of the opto-electrical conversion structure 100 and is electrically connected to the opto-electrical conversion structure 100. The second electrically-conductive structure 300 is disposed on the back surface 120 of the opto-electrical conversion structure 100 and is electrically connected to the opto-electrical conversion structure 100. The first electrically-conductive structure 200 includes a first transparent electrically-conductive layer 210, an electrode structure 220, and a second transparent electrically-conductive layer 230. The first transparent electrically-conductive layer 210 is disposed on the light receiving surface 110 of the opto-electrical conversion structure 100. The electrode structure 220 is disposed on the first transparent electrically-conductive layer 210. At least one portion of the first transparent electrically-conductive layer 210 is disposed between the electrode structure 220 and the light receiving surface 110 of the opto-electrical conversion structure 100. The second transparent electrically-conductive layer 230 covers the electrode structure 220 and the first transparent electrically-conductive layer 210.

The opto-electrical conversion structure 100 includes at least two layers of semiconductor layers. For example, the opto-electrical conversion structure 100 may include at least one p-type semiconductor layer and at least one n-type semiconductor layer, or may include at least one p-type semiconductor layer, at least one i-type semiconductor layer, and at least one n-type semiconductor layer. These semiconductor layers may be formed from, but should not be limited to, silicon, and also may be formed from other semiconductor materials which can convert optical energy into electrical energy, such as alloys or polymer materials. Furthermore, the semiconductor layers may be monocrystalline, polycrystalline, or amorphous forms. Moreover, the light can be only incident to the light receiving surface 110 of the opto-electrical conversion structure 100, or incident to both of the light receiving surface 110 and the back surface 120 of the opto-electrical conversion structure 100, and embodiments of the present disclosure are not limited thereto.

Since the second transparent electrically-conductive layer 230 of the present embodiment covers the electrode structure 220 and the first transparent electrically-conductive layer 210, carriers generated from the opto-electrical conversion structure 100 may flow to the electrode structure 220 directly through the first transparent electrically-conductive layer 210 or first through the first transparent electrically-conductive layer 210 and then through the second transparent electrically-conductive layer 230. In other words, a bottom surface of the second transparent electrically-conductive layer 230 is contacted with a top surface of the electrode structure 220, two side walls of the electrode structure 220, and a top surface of the first transparent electrically-conductive layer 210, and a bottom surface of the first transparent electrically-conductive layer 210 is contacted with the light receiving surface 110. The electrode structure 220 may be electrically connected to the opto-electrical conversion structure 100 through the first transparent electrically-conductive layer 210 and the second transparent electrically-conductive layer 230. Accordingly, even though the reduced size of the electrode structure 220 may result in a reduced contact area between the electrode structure 220 and the first transparent electrically-conductive layer 210, yet a large contact area exists between the second transparent electrically-conductive layer 230 and the electrode structure 220, i.e. the electrically-conductive area between the opto-electrical conversion structure 100 and the electrode structure 220 is increased, such that the carriers of the opto-electrical conversion structure 100 still can flow to the electrode structure 220 easily, and the resistance between the opto-electrical conversion structure 100 and the electrode structure 220 can be reduced. Once the resistance is reduced, the fill factor (FF) of the solar cell can be increased. Moreover, the light is incident to the solar cell from the second transparent electrically-conductive layer 230. After entering the second transparent electrically-conductive layer 230, most of the light can be reflected to the opto-electrical conversion structure 100 due to a total internal reflection interface between the second transparent electrically-conductive layer 230 and the external medium (such as air). Therefore, the second transparent electrically-conductive layer 230 can enhance the light capture efficiency, and increase the short circuit current density (Jsc) of the solar cell.

Reference is made to FIG. 2. In one or more embodiments, the thickness T1 of the first transparent electrically-conductive layer 210 can be about 10 nm to about 100 nm. In greater detail, a portion of the carriers of the opto-electrical conversion structure 100 can flow to the electrode structure 220 directly through the first transparent electrically-conductive layer 210. The resistance between the opto-electrical conversion structure 100 and the electrode structure 220 gets smaller when the thickness T1 of the first transparent electrically-conductive layer 210 gets thinner, such that the fill factor can be increased. However, the thickness T1 of the first transparent electrically-conductive layer 210 can be substantially greater than or equal to 10 nm to prevent atoms of the electrode structure 220 from diffusing into the opto-electrical conversion structure 100, thus avoiding reducing the quality of the solar cell.

Furthermore, a sum of the thickness T1 of the first transparent electrically-conductive layer 210 and the thickness T2 of the second transparent electrically-conductive layer 230 may be about 100 nm. For example, if the reflective index of the first transparent electrically-conductive layer 210 and that of the second transparent electrically-conductive layer 230 both are between 1.8 and 2.2, the first transparent electrically-conductive layer 210 and the second transparent electrically-conductive layer 230 may have better anti-reflection effects within a visible light wavelength range when the sum of the thickness T1 and T2 is about 100 nm. In other embodiments, however, the sum of the thickness T1 and T2 can be determined by the reflective index of the first transparent electrically-conductive layer 210 and that of the second transparent electrically-conductive layer 230, and embodiments of the present disclosure are not limited thereto.

In one or more embodiments, the first transparent electrically-conductive layer 210 and the second transparent electrically-conductive layer 230 can be formed from transparent conductive oxide (TCO), such as indium tin oxide (ITO), tin oxide (SnO₂), zinc oxide (ZnO), aluminum zinc oxide (AZO), gallium zinc oxide (GZO), indium zinc oxide (IZO), or any combination thereof, and embodiments of the present disclosure are not limited thereto.

In this embodiment, the first electrically-conductive structure 200 can further include a buffer layer 240 disposed between the electrode structure 220 and the second transparent electrically-conductive layer 230. Wherein the buffer layer 240 is cover on the top surface and the side walls of the electrode structure 220. So, the bottom surface of the second transparent electrically-conductive layer 230 is contacted with a top surface of the buffer layer 240, the two side walls of buffer layer 240, and the top surface of the first transparent electrically-conductive layer 210, and a bottom surface of buffer layer 240 is contacted with the top surface of the electrode structure 220, the two side walls of the electrode structure 220, and partial of top surface of the first transparent electrically-conductive layer 210, wherein the bottom surface of the first transparent electrically-conductive layer 210 is contacted with the light receiving surface 110. The buffer layer (or namely adhesion layer) 240 may enhance adhesion force between the second transparent electrically-conductive layer 230 and the electrode structure 220, such that the second transparent electrically-conductive layer 230 can be easily formed above the electrode structure 220. In one or more embodiments, the buffer layer 240 may be formed from at least one of zinc, titanium, tin, indium, or any combination thereof, and depends on the materials of the second transparent electrically-conductive layer 230 and the electrode structure 220.

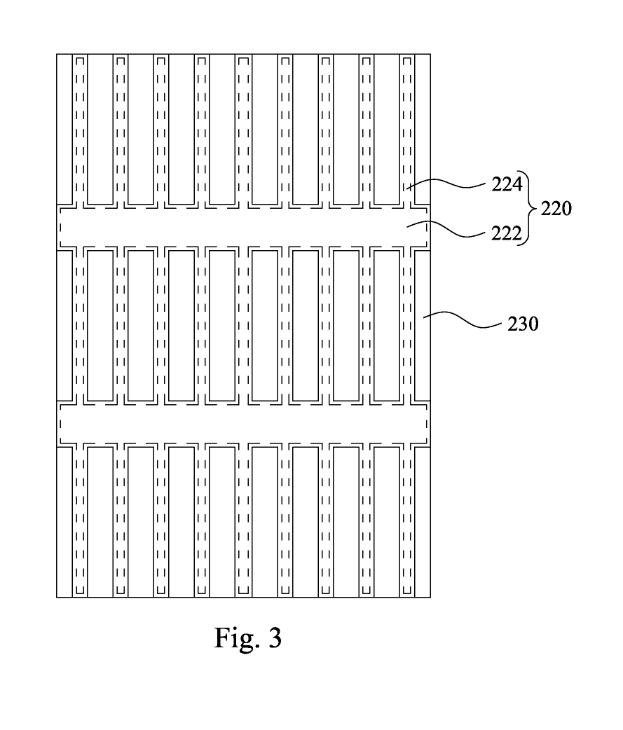

FIG. 3 is a top view of the solar cell in FIG. 1. Reference is made to FIGS. 2 and 3. In this embodiment, the electrode structure 220 may include bus electrodes 222 and finger electrodes 224. The finger electrodes 224 are interlacing arranged with the bus electrodes 222, and electrically connected to the bus electrodes 222. More specifically, the carriers of the opto-electrical conversion structure 100 can flow to the bus electrodes 222 and the finger electrodes 224 through the first transparent electrically-conductive layer 210 and the second transparent electrically-conductive layer 230. The carriers flowing to the finger electrodes 224 can then flow to the bus electrodes 222, and then flow to outside circuits along the bus electrodes 222.

Reference is made to FIG. 2. In this embodiment, the electrode structure 220 can be formed on or above the first transparent electrically-conductive layer 210 using the electroplating process, such that the size of the electrode structure 220 can be reduced. In the embodiment of FIG. 2, a width W of a side of the electrode structure 220 facing the first transparent electrically-conductive layer 210 can be about 40 nm. In greater detail, the manufacturer can form a patterned photoresist layer on the first transparent electrically-conductive layer 210, the pattern of the patterned photoresist layer is complemented with that of the electrode structure 220 in FIG. 3. Then, the manufacturer can form the electrode structure 220 using the electroplating process and then remove the patterned photoresist layer. However, since edges of the patterned photoresist layer may be inclined, the width of the electrode structure 220 formed thereafter changes with the height (or namely thickness) thereof. In other words, in this embodiment, the width of the finger electrodes 224 (referring to FIG. 3) is increased in a direction away from the first transparent electrically-conductive layer, and the cross sections may be mushroom-shaped, such as the shaped like inverted-taper shaped (or namely inverted-trapezoid shaped, or namely top wide and bottom narrow shaped). Therefore, an area of an orthogonal projection of the electrode structure 220 on the first transparent electrically-conductive layer 210 is substantially larger than the contact area between the electrode structure 220 and the first transparent electrically-conductive structure 210 if the second transparent electrically-conductive layer 230 does not cover the electrode structure 220, thus adversely reducing the light receiving area of the opto-electrical conversion structure 100. However, since the second transparent electrically-conductive layer 230 of the present embodiment covers the electrode structure 220, light can be total reflected in the second transparent electrically-conductive layer 230 and be guided to the opto-electrical conversion layer 100, so as to enhance the light capture efficiency and increase the short circuit current density (Jsc) of the solar cell.

In this embodiment, the electrode structure 220 comprises copper, and the electrode structure 220 can be formed on the first transparent electrically-conductive layer 210 using the copper plating process. Furthermore, for enhancing the efficiency of the copper plating process, a seed layer 250 can be formed on the first transparent electrically-conductive layer 210 before the electroplating process is performed. The seed layer 250 can be formed from electrically-conductive metal, such as copper. However, in other embodiments, the seed layer 250 may be formed from electrically-conductive polymers, such as poly(3,4-ethylenedioxythiophene):poly(styrene sulfonic acid) (PEDOT:PSS). Structurally, the seed layer 250 is disposed between the electrode structure 220 and the first transparent electrically-conductive layer 210 after the electroplating process is completed. In other words, the seed layer 250 is sandwich in between the electrode structure 220 and the first transparent electrically-conductive layer 210. So, a top surface of the seed layer 250 is contacted with the bottom surface of the electrode structure 220, a bottom surface of the seed layer 250 is contacted with the top surface of first transparent electrically-conductive layer 210, and side walls of the seed layer 250 are contacted with the bottom surface of buffer layer 240. The seed layer 250 has a thickness is substantially smaller than 100 nanometers (nm), for example.

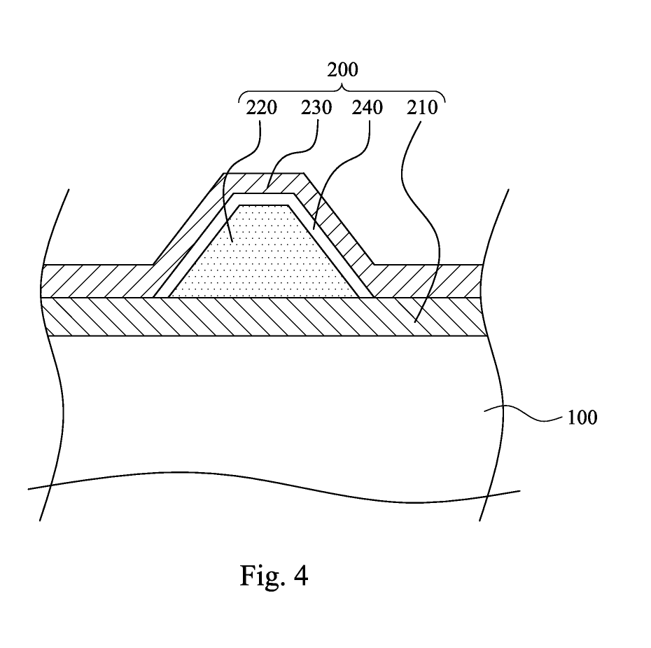

Reference is made to FIG. 4 which is a cross sectional view viewed along line A-A of FIG. 1 according to another embodiment. The difference between the present embodiment and the embodiment of FIG. 2 pertains to the shape of the electrode structure 220 and the configuration of the seed layer 250 (referring to FIG. 2). In this embodiment, the width of the finger electrode 224 (referring to FIG. 3) gets smaller in a direction away from the first transparent electrically-conductive layer 210 (or namely the width of the finger electrode 224 formed thereafter changes with the height (or namely thickness) thereof. For example, the cross-sectional shaped of the finger electrode 224 may be a regular trapezoid (or namely taper shaped, or namely top narrow and bottom wide shaped). Since the second transparent electrically-conductive layer 230 covers the electrode structure 220 and the first transparent electrically-conductive layer 210, the solar cell of the present embodiment can reduce the resistance and enhance the light capture efficiency.

In this embodiment, the electrode structure 220 may be a electrically-conductive adhesive including silver or other metals, and the electrode structure 220 can be formed on the first transparent electrically-conductive layer 210 using conductive paste screen printing process. The cross section of the electrode structure 220 is as shown in FIG. 4. Other relevant structural details of the present embodiment are all the same as the embodiment of FIG. 2, and thus are not described again herein.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A solar cell, comprising:
an opto-electrical conversion structure having a light receiving surface and a back surface opposite to the light receiving surface;
a first electrically-conductive structure which is disposed on the light receiving surface of the opto-electrical conversion structure and is electrically connected to the opto-electrical conversion structure, the first electrically-conductive structure comprising:
a first transparent electrically-conductive layer disposed on the light receiving surface of the opto-electrical conversion structure;
an electrode structure, wherein at least one portion of the first transparent electrically-conductive layer is disposed between the electrode structure and the light receiving surface of the opto-electrical conversion structure; and
a second transparent electrically-conductive layer covering the electrode structure and the first transparent electrically-conductive layer; and
a second electrically-conductive structure disposed on the back surface of the opto-electrical conversion structure.

2. The solar cell of claim 1, wherein the first electrically-conductive structure further comprises:
a buffer layer disposed between the electrode structure and the second transparent electrically-conductive layer, wherein the buffer layer is cover on a top surface and side wall of the electrode structure.

3. The solar cell of claim 2, wherein the buffer layer is formed from at least one of zinc, titanium, tin, and indium.

4. The solar cell of claim 1, wherein the first electrically-conductive structure further comprises:
a seed layer disposed between the electrode structure and the first transparent electrically-conductive layer.

5. The solar cell of claim 4, wherein the seed layer comprises copper.

6. The solar cell of claim 1, wherein a thickness of the first transparent electrically-conductive layer substantially ranges from 10 nm to 100 nm.

7. The solar cell of claim 1, wherein the electrode structure comprises:
a plurality of bus electrodes; and
a plurality of finger electrodes which are interlacing arranged with the bus electrodes and are electrically connected to the bus electrodes.

8. The solar cell of claim 7, wherein a width of the finger electrode is increasing in a direction away from the first transparent electrically-conductive layer.

9. The solar cell of claim 7, wherein a width of the finger electrode is decreasing in a direction away from the first transparent electrically-conductive layer.

10. The solar cell of claim 1, wherein the electrode structure comprises copper or silver.
